(19) United States
(12) Patent Application Publication
(10) Pub. No.: US 2025/0370008 A1
(43) Pub. Date: Dec. 4, 2025

(54) SIGNAL SWITCHING CIRCUIT AND SIGNAL SWITCH JIG

(71) Applicant: Fulian Precision Electronics (Tianjin) Co., LTD., Tianjin (CN)

(72) Inventors: WEI-MING LEE, New Taipei (TW); CHI-WEN CHEN, New Taipei (TW)

(21) Appl. No.: 18/963,897

(22) Filed: Nov. 29, 2024

(30) Foreign Application Priority Data
May 28, 2024 (CN) 202410666943.1

(51) Int. Cl. G01R 13/02

(52) U.S. Cl. CPC G01R 13/0272

(57) ABSTRACT

A signal switch circuit is connected between an oscilloscope and N signal input sources. The signal switch circuit includes N input terminals, an output terminal, and N-1 switch units. The N input terminals correspond to the N signal input sources respectively in one-to-one relationship. The output terminal is connected with a channel of the oscilloscope. Each of the N-1 switch units comprises a normal close terminal, a common terminal, a normal open terminal, and a control terminal. The signal switch circuit acquires an input signal from one of the signal input sources to output to the oscilloscope through the output terminal based on the control signal received by each of the control terminal of each of the N-1 switch units. A test efficiency is improved and a test cost is reduced. A signal switch jig is also provided.

### TECHNICAL FIELD

The present application generally relates to test technology, and particularly to a signal switch circuit and a signal switch jig.

### BACKGROUND

Waveforms of signals in different amplitudes over time can be observed by oscilloscopes. The oscilloscopes also may test different electric quantities, such as a voltage, a current, a frequency, a phase difference, and a modulation amplitude, and so on. However, channels of the general oscilloscope are limited, while testing a large number of to-be-measured signals, plugging operations are executed for multiple times, which lowers test efficiency.

There is room for improvement in the art.

### BRIEF DESCRIPTION OF THE DRAWINGS

Implementations of the present application will now be described, by way of example only, with reference to the attached figures.

FIG. 1 is a diagram illustrating an embodiment of an application environment of a signal switch circuit according to the present application.

FIG. 2 is a diagram illustrating an embodiment of a signal switch circuit according to the present application.

FIG. 3 is a circuit diagram illustrating an embodiment of the signal switch circuit of FIG. 2 according to the present application.

FIG. 4 is a diagram illustrating an embodiment of a signal switch jig with a door frame open according to the present application.

FIG. 5 a diagram illustrating an embodiment of the signal switch jig with the door frame of FIG. 4, with the door frame closed, according to the present application.

FIG. 6 is a diagram illustrating an embodiment of a circuit according to the present application.

### DETAILED DESCRIPTION

The following clearly describes the technical solution in embodiments of this application with reference to the accompanying drawings in the embodiments of the application.

It should be noted that, when a component is considered to be “connected” to another component, it can be directly connected to the another component or an intermediate element may exist therebetween. When a component is considered as to be “fixed” to another component, it can be directly on the another component or an intermediate element may exist therebetween. The terms used in the present application, such as “top”, “bottom”, “up”, “down”, “left”, “right”, “front”, “rear” and similar expressions used herein are for illustrative purposes only, and do not represent unique embodiments.

Unless otherwise defined, meanings of all technical and scientific terms used in the present application are the same as the those generally understood by persons skilled in the art of the present application. The terms used in the specification of the present application herein are used only to describe specific embodiments, and not intended to limit the preset application.

In the description of the present disclosure, unless other specified, “/” means “or”. For example, A/B may indicate A or B. In this application, “and/or” describes only an association relationship for describing associated objects and indicates that three relationship may exist. For example, A and/or B may indicate the following three cases: Only A exists, both A and B exist, and only B exists.

In the description of the present disclosure, the words such as “first”, “second”, and the like, are used to distinguish different objects, and do not limit quantities and execution sequences. In addition, the words such as “first”, “second”, do not necessarily limit a definite difference. In addition, terms “include” and “have”, and any variant thereof are intended to cover the non-exclusive inclusion.

Waveforms of signals in different amplitudes over time can be observed by oscilloscopes. The oscilloscopes also may test different electric quantities, such as a voltage, a current, a frequency, a phase difference, and a modulation amplitude, and so on. However, channels of the general oscilloscope are limited, while testing a large number of to-be-measured signals, plugging operations are executed for multiple times, which cause a test efficiency to be low.

Therefore, the present application provides a signal switch circuit and a signal switch jig, for simplifying manual operations, thus the test efficiency is improved and a test cost is reduced.

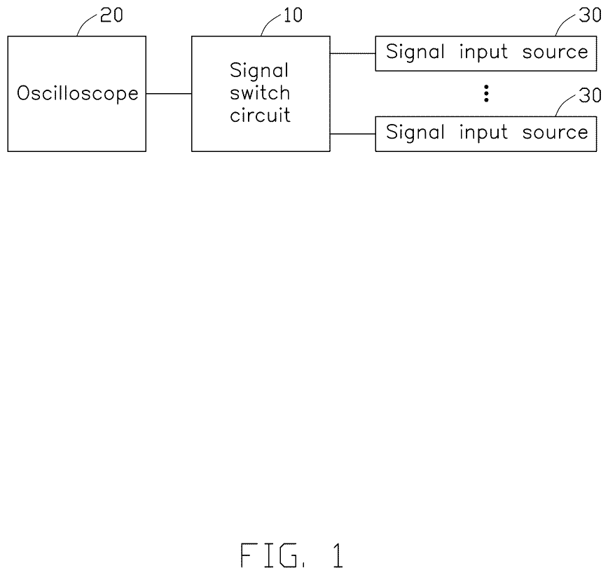

Referring to FIG. 1, FIG. 1 shows a diagram illustrating an application environment of the signal switch circuit 10. The signal switch 10 is electrically connected between an oscilloscope 20 and N signal input sources 30. N is an integer, being larger than or equal to 1. The signal switch circuit 10 selects one input signal from one of the N signal input sources 30, and outputs to the oscilloscope 20, for measuring by the oscilloscope 20. The present application do not limit the type of the signal input sources 30. The N signal input sources 30 may be any types ports or circuits for outputting an electrical signal, and so on.

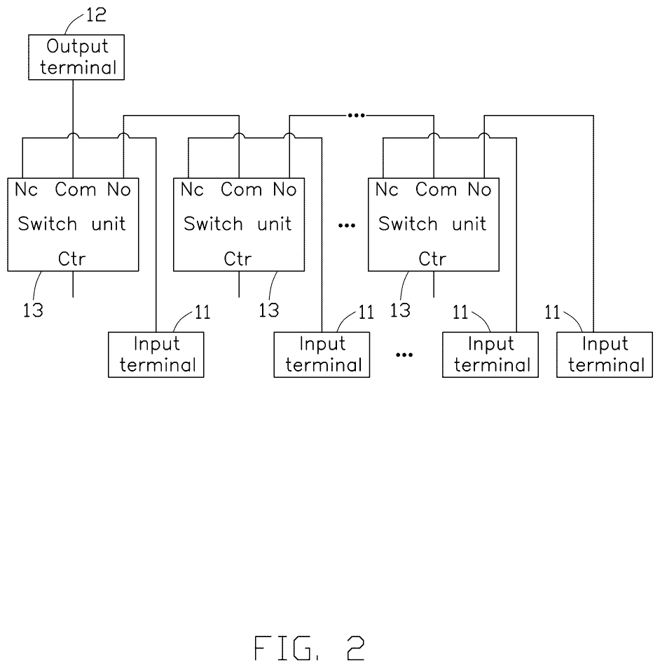

Referring to FIG. 2, FIG. 2 shows a diagram illustrates a signal switch circuit 10 provided by the present application. The signal switch circuit 10 includes N input terminals 11, an output terminal 12, and N-1 switch units 13.

The N input terminals 11 are electrically connected with the N signal input sources 30 respectively in one-to-one basis, for receiving a corresponding the input signal outputted by the corresponding signal input source 30.

The output terminal 12 is configured to connect to the channels of the oscilloscope 20.

Each of the N-1 switch units 13 includes a normal closed terminal Nc, a common terminal Com, a normal open terminal No, and a control terminal Ctr. The N-1 normal close terminals Nc are electrically connected to the N-1 input terminals 11 respectively, in one-to-one relationship. The N-1 switch units 13 are connected with each other to form a signal pathway. The common terminal Com of a first switch unit 13 of the N-1 switch units 13 at an end of the signal pathway is electrically connected to the output terminal 12. Each common terminal Com of each of second to (N-2)th switch units 13 of the N-1 switch units 13 is electrically connected to the normal open terminal No of an adjacent switch unit 13 of the N-1 switch units 13. The normal open terminal No of an (N-1)th switch unit 13 of the N-1 switch units 13 at an opposite end of the signal pathway is electrically connected to the Nth input terminal 11 of the N input terminals 11. The control terminal Ctr of each of the N-1 switch units 13 is configured to receive a control signal. While the received control signal is at a first voltage level signal, in a same switch unit 13, an electrical connection between the normal closed terminal Nc and the common terminal Com is established, and an electrical connection between the normal open terminal No and the common terminal Com is cut off. While the received control signal is at a second voltage level signal, in a same switch unit 13, the electrical connection between the normal closed terminal Nc and the common terminal Com is cut off, and the electrical connection between the normal open terminal

No and the common terminal Com is established. The signal switch circuit 10 acquires an input signal from one of the signal input sources 30 to output to the oscilloscope 20 through the output terminal 12 based on the control signal received by each of the control terminal Ctr.

The first voltage level signal is one of a high level signal and a low level signal, and the second voltage level signal is another of the high level signal and the low level signal. In one embodiment of the present application, the following uses an example in which the first voltage level signal is the low level signal and the second voltage level signal is the high level signal. The low level signal may be a voltage signal at 0V, and the high level signal may be a voltage signal at 3.3V. The present application does not limit the specific value of the low level signal and the high level signal, the voltage of the high level signal is larger than the voltage of the low level signal.

It is understood that, the operation principle of the signal switch circuit 10 will described as below.

As the circuit structure shown in FIG. 2, when the received control signal of each of the N-1 switch units 13 is at the first voltage level signal, the input signal received by the input terminal 11 of the first switch unit 13 is directly outputted to the oscilloscope 20 through the output terminal 12, the normal close terminal Nc of the first switch unit 13, and the common terminal Com of the first switch unit 13, and the electrical connection between the common terminal Com and the normal open terminal No in the first switch unit 13 is cut off. Due to the normal open terminal No of the first switch unit 13 is electrically connected to the common terminal Com of a second switch unit 13 of the N-1 switch units 13, the common terminal Com of the first switch unit 13 is disconnected with the common terminal Com of the second switch 13. Therefore, the input signal at the input terminal 11 in the second switch unit 13 of the N-1 switch units 13 connected with the common terminal Com of the second switch unit 13 fails to transmit to the output terminal 12 through the common terminal Com of the first switch unit 13. Similarly, other switch units 13 of the N-1 switch units 13 also fail to transmit the input signal to the output terminal 12 through the first switch unit 13. Therefore, when the received control signal of each of the N-1 switch units 13 is at the first voltage level signal, the first switch unit 13 in the signal switch circuit 10 acquires the input signal of the corresponding connected signal input source 30 and outputs to the oscilloscope 20.

When the received control signal of the second switch units 13 is at the second voltage level signal, and the received control signals of the first and a third to (N-1)th switch units 13 of the N-1 switch units 13 are at the first voltage level signal, according to the description above, the input signal received by the input terminal 11 in the first switch unit 13 is directly outputted to the oscilloscope 20 through the normal close terminal Nc, the common terminal Com, and the output terminal 12. At the same time, the received control signal at the control terminal Ctr of the second switch units 13 is at the second voltage, the electrical connection between the common terminal Com and the normal open terminal No in the second switch unit 13 is established, and the electrical connection between the common terminal Com and the normal open terminal No in the first switch unit 13 is cut off, thus the input signal at the input terminal 11 in the second switch unit 13 connected with the common terminal Com of the second switch unit 13 still fails to transmit to the output terminal 12 through the common terminal Com of the first switch unit 13. Therefore, when the received control signal of the second switch units 13 is at the second voltage level signal, and the received control signals of the rest of the switch units 13 are at the first voltage level signal, the first switch unit 13 in the signal switch circuit 10 acquires the input signal of the corresponding signal input source 30 and outputs to the oscilloscope 20.

Similarly, in other embodiments, the signal switch circuit 10 obtains the input signal from one of the N signal input sources 30 and outputs to the oscilloscope 20 based on the receiving control signal received by the control terminal Ctr of each of the N-1 switch units 13.

It is understood that, the signal switch circuit 10 provided by the present application,

sets the output terminal 12, the N input terminals 11, and the N-1 switch units 13, controls the N-1 switch units 13 to acquire the input signal one of the N signal input sources 30 connected with the N input terminals 11, and outputs the acquired input signal of one of the N signal input sources 30 to the oscilloscope 20 through the output terminal 12. Therefore, the signal switch circuit 10 provided by the present application multiplexes the input channel of the oscilloscope 20, decreases the times of the plugging operations of the signal switch circuit 10 while testing the plurality of the signal input sources 30, and the test efficiency is improved.

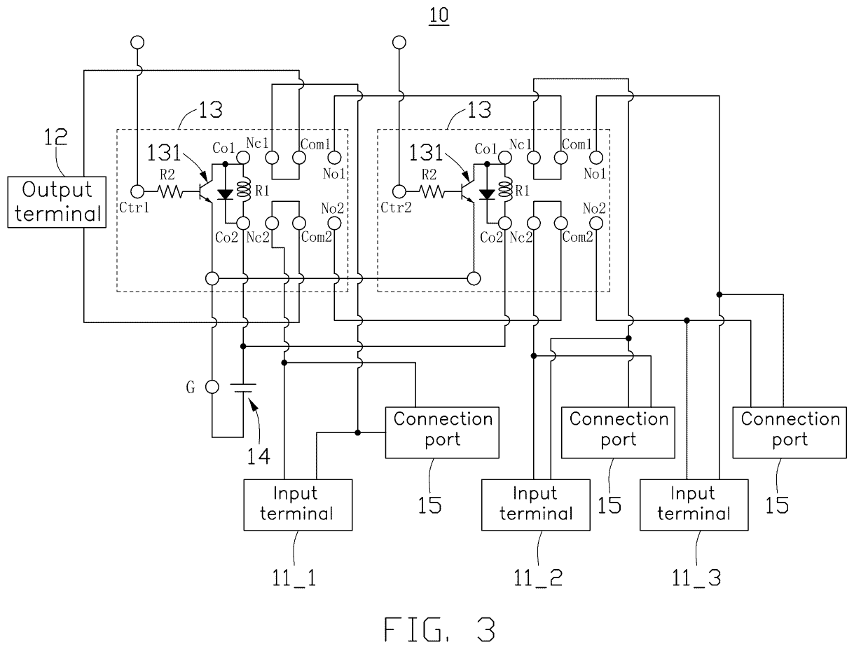

Referring to FIG. 3, FIG. 3 shows a circuit diagram of the signal switch circuit 10 of an embodiment of the present application. In FIG. 3, the signal switch circuit 10 includes two switch units 13. The signal switch circuit 10 of the present application will further explain based on the circuit diagram shown in FIG. 3.

In some embodiments, the normal open terminal No includes a first normal open contact No1 and a second normal open contact No2. The common terminal Com includes a first common contact Com1 and a second common contact Com2. The normal close terminal Nc includes a first normal close contact Nc1 and a second normal close contact Nc2.

The first common contact Com1 of the first switch unit 13 of the N-1 switch units 13 at the end of the signal pathway is electrically connected with a first terminal of the output terminal 12, and the second common contact Com2 of the first switch unit 13 of the N-1 switch units 13 at the end of the signal pathway is electrically connected with a second terminal of the output terminal 12.

The first normal open contact No1 of the (N-1)th switch unit 13 of the N-1 switch units 13 at the opposite end of the signal pathway is electrically connected to a first terminal of the Nth input terminal 11_3, and the second normal open contact No2 of the (N-1)th switch unit 13 of the N-1 switch units 13 at the opposite end of the signal pathway is electrically connected to a second terminal of the Nth input terminal 11_3. The first normal open contact No1 of each of the second to (N-2)th switch units 13 of the N-1 switch units 13 is electrically connected to the first common contact Com1 of the adjacent switch unit 13. The second normal open contact No2 of each of the second to (N-2)th switch units 13 of the N-1 switch units 13 is electrically connected to the second common contact Com2 of the adjacent switch unit 13.

In each of the N-1 switch units, the first normal close contact Nc1 is electrically connected to the first common contact Com1 and the first terminal of the corresponding input terminal 11. In each of the N-1 switch units, the second normal close contact Nc2 is electrically connected to the second common contact Com2 and the second terminal of the corresponding input terminal 11.

In some embodiments, the signal switch circuit 10 further includes a power supply 14. Each of the N-1 switch units 13 further includes a switch transistor 131, a first connection terminal Co1, and a second connection terminal Co2.

In each of the N-1 switch unit 13, the first connection terminal Co1 is electrically connected to a first terminal of the switch transistor 131, and the second connection terminal Co2 is electrically connected to the first connection terminal Co1 and a positive terminal of the power supply 14. A negative terminal of the power supply 14 is electrically connected to a second terminal of the switch transistor 131. A third terminal of the switch transistor 131 is electrically connected to the control terminal Ctr.

In one embodiment, the switch transistor 131 may be a NPN triode, the first terminal of the switch transistor 131 is a collector, the second terminal of the switch transistor 131 is an emitter, the third terminal of the switch transistor 131 is a base. In other embodiments, the switch transistor 131 may be replaced by a MOS transistor, an Insulate Gate Bipolar Transistor (IGBT), a relay, or other circuits with a switch function, but not being limited.

It is understood that, in each of the N-1 switch units 13, when the control terminal Ctr receives the first voltage level signal, the switch transistor 131 is turned off. The electrical connection between the first connection terminal Co1 and the first normal close contact Nc1 is cut off, and the electrical connection between the first normal close contact Nc1 and the first common contact Com1 is established. The electrical connection between second connection terminal Co2 and the second normal close contact Nc2 is cut off, and the electrical connection between the second normal close contact Nc2 and the second common contact Com2 is established.

In each of the N-1 switch units 13, when the control terminal Ctr receives the second voltage level signal, the switch transistor 131 is turned on. The electrical connection between the first connection terminal Co1 and the first normal close contact Nc1 is established, and the electrical connection between the first normal close contact Nc1 and the first common contact Com1 is cut off. The electrical connection between second connection terminal Co2 and the second normal close contact Nc2 is established, and the electrical connection between the second normal close contact Nc2 and the second common contact Com2 is cut off.

In some embodiments, each of the N-1 switch units 13 further includes a first current limiting resistor R1, a second current limiting resistor R2, and a diode D. In each of the N-1 switch units 13, the second connection terminal Co2 is electrically connected to the first connection terminal Co1 through the first current limiting resistor R1. An anode of the diode D is electrically connected to a node between the first terminal of the switch transistor 131 and the first connection terminal Co1, and a cathode of the diode D is electrically connected to the second connection terminal Co2. The third terminal of the switch transistor 131 is electrically connected to the control terminal Ctr through the second current limiting resistor R2.

It is understood that, by setting the first current limiting resistor R1 and the second current limiting resistor R2, an overcurrent risk is reduced. By setting the diode D, a current from the second terminal of the switch transistor 131 to the first terminal is prevented. Therefore, a safe risk of the signal switch circuit 10 is reduced by the first current limiting resistor R1, the second current limiting resistor R2, and the diode D.

In some embodiments, each of the N-1 switch units 13 further includes a connection port 15. In each of the N-1 switch units 13, a terminal of the connection port 15 is electrically connected to a node between the first normal close contact Nc1 and the first terminal of the corresponding input terminal 11. A second terminal of the connection port 15 is electrically connected to a node between the second normal close contact Nc2 and the second terminal of the corresponding input terminal 11.

Therefore, by setting the connection port 15, it is convenience to add external electrical components in the signal switch circuit 10, for increasing a flexibility of the signal switch circuit 10. For example, in some embodiments, the connection port 15 is electrically connected to a capacitor, for filtering interference signals in the signal switch circuit 10.

In some embodiments, the input terminal 11 and the output terminal 12 may be Bayonet Nut Connector (BNC) ports, the connection port 15 may be a terminal holder with two contacts. In other embodiments, the input terminal 11, the output terminal 12, and the connection port 15 may by other types of ports, the present application does not limit the types of the input terminal 11, the output terminal 12, and the connection port 15.

It is understood that, in some embodiments, the following chart shows a control logic of the signal switch circuit 10 as shown in FIG. 3 for acquiring the input signal of one of the input terminals 11 being connected to the signal input sources 30 and outputting the acquired input signal to the oscilloscope 20.

TABLE 1
Control logic of the signal switch circuit 10

| Ctr1 | Ctr2 | 11_1 | 11_2 | 11_3 |
|---|---|---|---|---|
| First voltage | First voltage | ✓ | | |
| level signal | level signal | | | |
| First voltage | Second voltage | ✓ | | |
| level signal | level signal | | | |
| Second voltage | First voltage | | ✓ | |
| level signal | level signal | | | |
| Second voltage | Second voltage | | | ✓ |
| level signal | level signal | | | |

As shown in table 1, different combinations of the control signal of each of the two switch units 13 controls the signal switch circuit 10 to acquire the input signal of one of the input terminals 11 being connected to the signal input sources 30 and output the acquired input signal to the oscilloscope 20.

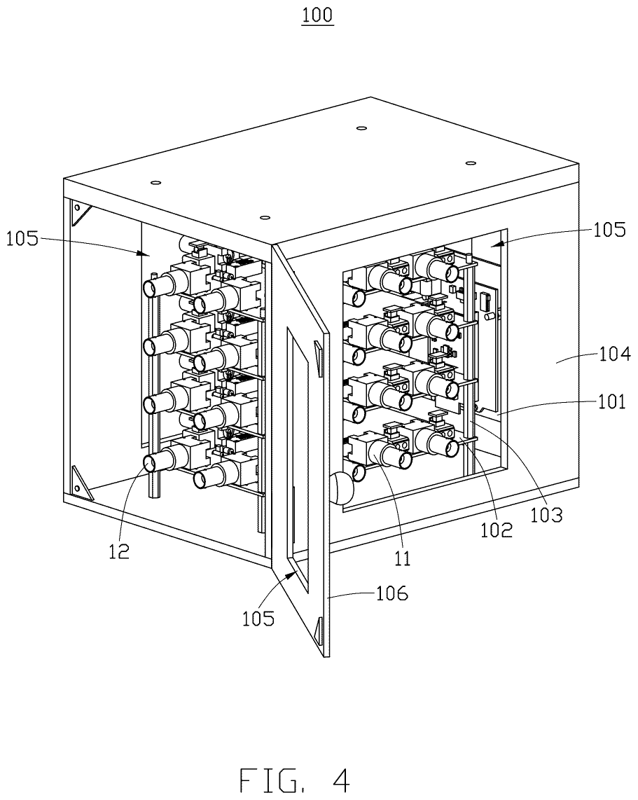

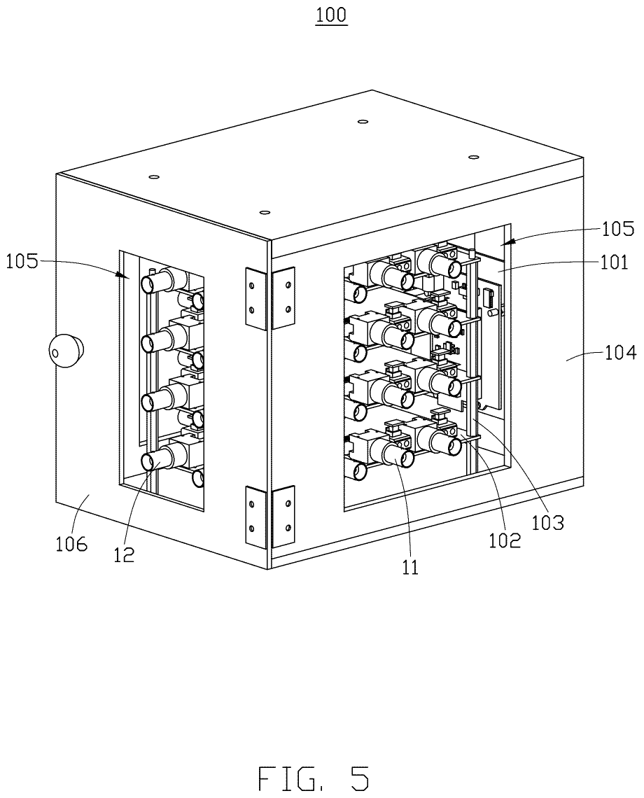

Referring to FIGS. 4 and 5, the present application further provides a signal switch jig 100. The signal switch jig 100 includes a controller 101 and at least one signal switch circuit 10. The controller 101 is electrically connected to the control terminal Ctr of each of the N-1 switch units 10, and is configured to output the control signal to the control terminal of each of the N-1 switch units 10.

The controller 101 may be a central processing unit (CPU), and also may be other general purpose processor, a digital signal processor (DSP), an Application Specific Integrated Circuit (ASIC), a Field-Programmable Gate Array (FPGA) or other programmable logic devices, discrete gate or transistor logic devices, discrete hardware components, and so on. The general purpose processor may be a microprocessor or any conventional processor. For example,, the controller 101 may be a Arduino, the present application does not limit.

In some embodiments, the signal switch jig 100 may be include eight signal switch circuits 10. Each of the eight signal switch circuits 10 sets with three input terminals 11, for electrically connected with three signal input sources 30. Therefore, the signal switch jig 100 may be electrically connected to twenty-four signal input sources 30. The signal switch jig 100 controls the eight signal switch circuits 10 by the controller 101, for acquire any one input signal of the twenty-four signal input sources 30 and outputting the acquired input signal to the oscilloscope 20. Thus, the test efficiency is improved and the test cost is reduced.

Further, the controller 101 sets with control programs, for executing a corresponding input instruction of operators, the input signal of one of the signal input sources 30 is automatically selected and outputted to the oscilloscope 20. Therefore, the related operations of the operators are simplified.

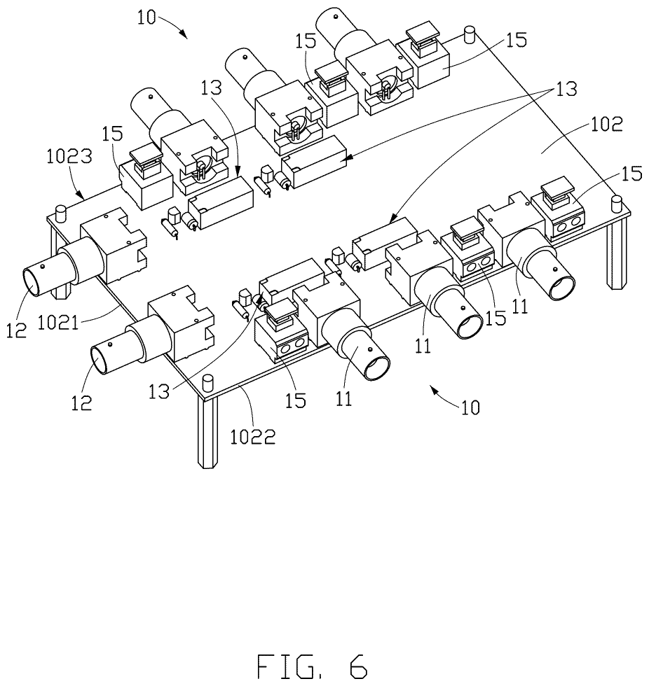

The signal switch jig 100 further includes a plurality of printed circuit boards (PCBs) 102. Each of the PCBs 102 is configured to embed the at least one signal switch circuit 10. For example, referring to FIG. 6, in some embodiments, the PCB 102 may embed two signal switch circuits 10.

The PCB 102 includes a first side 1021, a second side 1022, and a third side 1023. The second side 1022 and the third side 1023 are adjacent to the first side 1021. The output terminal 12 of each of the two signal switch circuits 10 is disposed on the first side 1021, all the input terminals 11 of one of the two signal switch circuits 10 are disposed on the second side 1022, and all the input terminals 11 of another of the two signal switch circuits 10 are disposed on the third side 1023.

Referring to FIGS. 4 and 5 again, in some embodiments, the signal switch jig 100 further includes a support frame 103. The support frame 103 is disposed between the two PCBs 102, for separating the two PCBs 102, which are disposed in an overlapped manner. Specifically, an end of the support frame 103 is connected to a side of each of the two PCBs 102 with the input terminals 11 and the output terminal 12, and an opposite end of the support frame 103 is connected to a side of each of the two PCBs 102 without the input terminals 11 and the output terminal 12. Four supporting frames 103 are disposed on four corners of each of the two PCBs 102 respectively. In that means, the four supporting frames 103 are disposed between the two PCBs 13. Therefore, the signal switch jig 100 may include more PCBs 102, the number of the signal switch circuits 10 may be more, and the number of the input signal sources 30 connected with the signal switch jig 100 may be more.

Referring to FIGS. 4 and 5 again, in some embodiments, the signal switch jig 100 further includes a shell frame 104. The shell frame 104 is configured to receive the at least one signal switch circuit 10 and the controller 101. The controller 101 is disposed on an inner sidewall of the shell frame 104, and a space formed by the shell frame 104 is configured to receive the multiple PCBs 102. Therefore, capabilities in protection against drops and shock resistant of the signal switch jig 100 may be improved.

The shell frame 104 defines a plurality of notches 105. Each of the plurality of the notches 105 corresponds to the input terminals 11 and the output terminal 12 of the at least one signal switch circuit 10. Therefore, it is convenience for the operators to connect the signal switch jig 100 with the oscilloscope 20 and the signal input sources 30.

In some embodiments, the frame 104 further include a door frame 106, which is capable of being opened or closed. Therefore, it is convenience for the operators to service the signal switch circuit 10 in the signal switch jig 100.

Based on foregoing descriptions, the signal switch jig 100 provided by the present application sets the controller 101 and the at least one signal switch circuit 10, for extending the number of the connected signal input sources 30, the test operations of the operators is simplified. Therefore, the test efficiency is improved.

It should be noted that the above accompanying drawings are only schematic descriptions of the processes included in the methods according to the exemplary embodiments of the present application, and are not intended to limit.

The present application is not limited to the above specific embodiments. Those skilled in the art will easily understand that there are many alternatives to the test jig 10 of the present application without departing from the principles and scope of the present application. The scope of the present application is subject to the contents of the claims.

What is claimed is:

1. A signal switch circuit connected between an oscilloscope and N signal input sources, the signal switch circuit comprises:
N input terminals, corresponding to the N signal input sources, respectively, in an one-to-one relationship;
an output terminal connected with a channel of the oscilloscope; and
N-1 switch units, wherein each of the N-1 switch units comprises a normal close terminal, a common terminal, a normal open terminal, and a control terminal; the N-1 normal close terminals are electrically connected to N-1 input terminals of the N input terminals, respectively, in an one-to-one relationship, the common terminal of a first switch unit of the N-1 switch units is electrically connected to the output terminal, and each common terminal of each of a second to an (N-1)th switch units of the N-1 switch units is electrically connected to the normal open terminal of an adjacent switch unit of the N-1 switch units; the normal open terminal of an (N-1) th switch unit is electrically connected to an Nth input terminal of the N input terminals; the control terminal is configured to receive a control signal; when the control signal is at a first voltage level signal, in a same switch unit, an electrical connection between the normal closed terminal and the common terminal is established, and an electrical connection between the normal open terminal and the common terminal is cut off; when the received control signal is at a second voltage level signal, in a same switch unit, the electrical connection between the normal closed terminal and the common terminal is cut off, and the electrical connection between the normal open terminal and the common terminal is established; the signal switch circuit acquires an input signal from one of the N signal input sources to output to the oscilloscope through the output terminal based on the control signal received by each of the control terminal.

2. The signal switch circuit of claim 1, wherein the normal open terminal comprises a first normal open contact and a second normal open contact; the common terminal comprises a first common contact and a second common contact; the normal close terminal comprises a first normal close contact and a second normal close contact;
the first common contact of the first switch unit is electrically connected with a first terminal of the output terminal, and the second common contact of the switch unit at the end of the signal pathway is electrically connected with a second terminal of the output terminal an output terminal;
the first normal open contact of the (N-1)th switch unit is electrically connected to a first terminal of the Nth input terminal of the N input terminals, and the second normal open contact at the opposite end of the signal pathway is electrically connected to a second terminal of the Nth input terminal; the first normal open contact of each of N-2 switch units of the N-1 switch units is electrically connected to the first common contact of the adjacent switch unit; the second normal open contact of each of the N-2 switch units is electrically connected to the second common contact of the adjacent switch unit; and
in each of the N-1 switch units, the first normal close contact is electrically connected to the first common contact and the first terminal of a corresponding input terminal of the N input terminals, the second normal close contact is electrically connected to the second common contact and the second terminal of the corresponding input terminal.

3. The signal switch circuit of claim 2, further comprising a power supply; each of the N-1 switch units further comprises a switch transistor, a first connection terminal, and a second connection terminal; in each of the N-1 switch unit, the first connection terminal is electrically connected to a first terminal of the switch transistor, and the second connection terminal is electrically connected to the first connection terminal and a positive terminal of the power supply; a negative terminal of the power supply is electrically connected to a second terminal of the switch transistor;
a third terminal of the switch transistor is electrically connected to the control terminal.

4. The signal switch circuit of claim 3, wherein each of the N-1 switch units further comprises a first current limiting resistor, a second current limiting resistor, and a diode; in each of the N-1 switch units, the second connection terminal is electrically connected to the first connection termina through the first current limiting resistor; an anode of the diode is electrically connected to a node between the first terminal of the switch transistor and the first connection terminal, and a cathode of the diode is electrically connected to the second connection terminal; the third terminal of the switch transistor is electrically connected to the control terminal through the second current limiting resistor.

5. The signal switch circuit of claim 2, wherein each of the N-1 switch units further comprises a connection port; in each of the N-1 switch units, a terminal of the connection port is electrically connected to a node between the first normal close contact and the first terminal of the corresponding input terminal; a second terminal of the connection port is electrically connected to a node between the second normal close contact and the second terminal of the corresponding input terminal.

6. The signal switch circuit of claim 5, wherein the N input terminals and the output terminal are Bayonet Nut Connector (BNC) ports; the connection ports is a terminal holder with two contacts.

7. A signal switch jig comprises:
a controller; and
at least one signal switch circuit connected between an oscilloscope and N signal input sources; the at least one signal switch circuit comprises:
N input terminals, corresponding to the N signal input sources, respectively in an one-to-one relationship;
an output terminal connected with a channel of the oscilloscope; and
N-1 switch units, wherein each of the N-1 switch units comprises a normal close terminal, a common terminal, a normal open terminal, and a control terminal; the N-1 normal close terminals are electrically connected to N-1 input terminals of the N input terminals, respectively in one-to-one relationship, the common terminal of a first switch unit of the N switch units is electrically connected to the output terminal, and each common terminal of each of a second to an (N-2)th switch unit of the (N-1) switch units is electrically connected to the normal open terminal of an adjacent switch unit of the N-1 switch units; the normal open terminal of an (N-1) th switch unit is electrically connected to an Nth input terminal of the N input terminals; the control terminal is configured to receive a control signal; when the control signal is at a first voltage level signal, in a same switch unit, an electrical connection between the normal closed terminal and the common terminal Com is established, and an electrical connection between the normal open terminal and the common terminal is cut off; when the received control signal is at a second voltage level signal, in a same switch unit, the electrical connection between the normal closed terminal and the common terminal is cut off, and the electrical connection between the normal open terminal and the common terminal is established; the signal switch circuit acquires an input signal from one of the signal input sources to output to the oscilloscope through the output terminal based on the control signal received by each of the control terminal.

8. The signal switch jig of claim 7, wherein the normal open terminal comprises a first normal open contact and a second normal open contact; the common terminal comprises a first common contact and a second common contact; the normal close terminal comprises a first normal close contact and a second normal close contact;
the first common contact of the first switch unit is electrically connected with a first terminal of the output terminal, and the second common contact of the switch unit at the end of the signal pathway is electrically connected with a second terminal of the output terminal an output terminal;
the first normal open contact of the (N-1)th switch unit at the opposite end of the signal pathway is electrically connected to the first terminal of the Nth input terminal of the N input terminals, and the second normal open contact at the opposite end of the signal pathway is electrically connected to a second terminal of the Nth input terminal; the first normal open contact of each of N-2 switch units of the N-1 switch units is electrically connected to the first common contact of the adjacent switch unit; the second normal open contact of each of the N-2 switch units is electrically connected to the second common contact of the adjacent switch unit; and
in each of the N-1 switch units, the first normal close contact is electrically connected to the first common contact and the first terminal of a corresponding input terminal of the N input terminals, the second normal close contact is electrically connected to the second common contact and the second terminal of the corresponding input terminal.

9. The signal switch jig of claim 8, wherein further comprising a power supply; each of the N-1 switch units further comprises a switch transistor, a first connection terminal, and a second connection terminal; in each of the N-1 switch unit, the first connection terminal is electrically connected to a first terminal of the switch transistor, and the second connection terminal is electrically connected to the first connection terminal and a positive terminal of the power supply;
a negative terminal of the power supply is electrically connected to a second terminal of the switch transistor; a third terminal of the switch transistor is electrically connected to the control terminal.

10. The signal switch jig of claim 9, wherein the normal open terminal comprises a first normal open contact and a second normal open contact; the common terminal comprises a first common contact and a second common contact; the normal close terminal comprises a first normal close contact and a second normal close contact;
the first common contact of the switch unit at the end of the signal pathway is electrically connected with a first terminal of the output terminal, and the second common contact of the switch unit at the end of the signal pathway is electrically connected with a second terminal of the output terminal an output terminal;
the first normal open contact of the switch unit at the opposite end of the signal pathway is electrically connected to a first terminal of the Nth input terminal, and the second normal open contact at the opposite end of the signal pathway is electrically connected to a second terminal of the Nth input terminal; the first normal open contact of each of the N-2 switch units is electrically connected to the first common contact of the adjacent switch unit; the second normal open contact of each of the N-2 switch units is electrically connected to the second common contact of the adjacent switch unit; and
in each of the N-1 switch units, the first normal close contact is electrically connected to the first common contact and the first terminal of the corresponding input terminal, the second normal close contact is electrically connected to the second common contact and the second terminal of the corresponding input terminal.

11. The signal switch jig of claim 10, wherein each of the N-1 switch units further comprises a first current limiting resistor, a second current limiting resistor, and a diode; in each of the N-1 switch units, the second connection terminal is electrically connected to the first connection termina through the first current limiting resistor; an anode of the diode is electrically connected to a node between the first terminal of the switch transistor and the first connection terminal, and a cathode of the diode is electrically connected to the second connection terminal; the third terminal of the switch transistor is electrically connected to the control terminal through the second current limiting resistor.

12. The signal switch jig of claim 8, wherein each of the N-1 switch units further comprises a connection port; in each of the N-1 switch units, a terminal of the connection port is electrically connected to a node between the first normal close contact and the first terminal of the corresponding input terminal; a second terminal of the connection port is electrically connected to a node between the second normal close contact and the second terminal of the corresponding input terminal.

13. The signal switch jig of claim 12, wherein the N input terminals and the output terminal are Bayonet Nut Connector (BNC) ports; the connection port is a terminal holder with two contacts.

14. The signal switch jig of claim 7, further comprising a plurality of printed circuit boards (PCBs); each of the plurality of the PCBs is configured to embed the at least one signal switch circuit.

15. The signal switch jig of claim 14, wherein the signal switch jig comprises two signal switch circuits; each of the plurality of the PCBs comprises a first side, a second side, and a third side;
the second side and the third side are adjacent to the first side; the output terminal of each of the two signal switch circuit is disposed on the first side, all the input terminals of one of the two signal switch circuits are disposed on the second side, and all the input terminals of another one of the two signal switch circuits are disposed on the third side.

16. The signal switch jig of claim 15, wherein the signal switch jig further comprises two PCBs and a support frame; the support frame is disposed between the two PCBs, and configured for separating the two PCBs, the two PCBs are disposed in an overlapped manner.

17. The signal switch jig of claim 7, further comprising a shell frame; the shell frame is configured to receive the at least one signal switch circuit and the controller; the controller is disposed on an inner sidewall of the shell frame.

18. The signal switch jig of claim 17, wherein the shell frame defines a plurality of notches; each of the plurality of the notches corresponds to the N input terminals and the output terminal of the at least one signal switch circuit.
